(19) United States
(12) Patent Application Publication
(10) Pub. No.: US 2025/0306234 A1
(43) Pub. Date: Oct. 2, 2025

(54) SENSOR UNIT

(71) Applicant: CANON KABUSHIKI KAISHA, Tokyo (JP)

(72) Inventor: TAKUMI IDE, Tokyo (JP)

(21) Appl. No.: 19/088,648

(22) Filed: Mar. 24, 2025

(30) Foreign Application Priority Data
Mar. 26, 2024 (JP) 2024-049224
Dec. 19, 2024 (JP) 2024-223878

(51) Int. Cl. G01V 8/12; G02B 26/04; H01L 25/16

(52) U.S. Cl. CPC G01V 8/12; G02B 26/04; H01L 25/167

(57) ABSTRACT

A sensor unit includes a substrate on which a light-emitting element and a light-receiving element are placed, the substrate including a slit between the light-emitting element and the light-receiving element, the slit being obtained by cutting out the substrate from one side of the substrate to an inside of the substrate, and a flag including a light-blocking portion configured to block light that travels from the light-emitting element toward the light-receiving element through the slit, wherein the sensor unit detects the flag in a light-blocking state where the light-blocking portion of the flag blocks the light traveling from the light-emitting element toward the light-receiving element, wherein the flag includes a wall portion configured to cover two directions perpendicular to each other, and the wall portion covers one of the light-emitting element and the light-receiving element.

### BACKGROUND

### Field

The present disclosure relates to a sensor unit for detecting a flag using a light-emitting element and a light-receiving element.

### Description of the Related Art

A photointerrupter having the following configuration is known. That is, the photointerrupter includes a light-emitting element, such as a light-emitting diode (LED), and a light-receiving element, such as a phototransistor, and functions as a sensor unit for detecting a flag using the fact that light is blocked by the flag when the flag passes through a space between the light-emitting element and the light-receiving element.

Japanese Patent Application Laid-Open No. 2015-124066 discusses an apparatus having a configuration in which a photointerrupter incorporated in an image forming apparatus detects passage of a sheet by allowing a light-blocking flag, which is configured to operate during passage of a sheet, to pass through a space between a light-emitting portion and a light-receiving portion.

In a case where a photointerrupter incorporated in an apparatus is used to detect passage of a sheet, like in the apparatus discussed in Japanese Patent Application Laid-Open No. 2015-124066, depending on the layout of surrounding members, light emitted from the light-emitting portion can be reflected on the surrounding members and can reach the light-receiving portion as stray light even when the light is blocked by the light-blocking flag. This may cause false detection by the sensor.

### SUMMARY

Accordingly, the present disclosure is directed to providing a sensor unit capable of preventing false detection due to stray light.

According to some embodiments, a sensor unit includes a substrate on which a light-emitting element and a light-receiving element are placed, the substrate including a slit between the light-emitting element and the light-receiving element, the slit being obtained by cutting out the substrate from one side of the substrate to an inside of the substrate, and a flag including a light-blocking portion configured to block light that travels from the light-emitting element toward the light-receiving element through the slit, wherein the sensor unit detects the flag in a light-blocking state where the light-blocking portion of the flag blocks the light traveling from the light-emitting element toward the light-receiving element, wherein the flag includes a wall portion configured to cover two directions perpendicular to a surface of the light-blocking portion, the two directions being perpendicular to each other, and wherein, in the light-blocking state, the wall portion covers one of the light-emitting element and the light-receiving element in a direction perpendicular to the substrate and in a direction parallel to the substrate and in which the substrate is cut out by the slit.

According to an aspect of the present disclosure, it is possible to provide a sensor unit capable of preventing false detection due to stray light.

Further features of the present disclosure will become apparent from the following description of exemplary embodiments with reference to the attached drawings.

### BRIEF DESCRIPTION OF THE DRAWINGS

FIGS. 1A and 1B are perspective views each illustrating a sensor unit as a first example according to a first exemplary embodiment.

FIG. 2 is a circuit diagram illustrating an optical sensor according to the first exemplary embodiment.

FIG. 3 is a top view of the optical sensor.

FIG. 4 is a side view of the optical sensor.

FIG. 5 is a perspective view of the sensor unit as the first example according to the first exemplary embodiment.

FIGS. 6A and 6B are perspective views each illustrating a sensor unit as a second example according to the first exemplary embodiment.

FIGS. 7A and 7B are perspective views each illustrating the sensor unit according to a second exemplary embodiment.

FIG. 8 is a side view of the sensor unit according to the second exemplary embodiment.

FIG. 9 is a side view of the sensor unit according to the second exemplary embodiment.

FIGS. 10A to 10D are side views each illustrating the sensor unit according to the second exemplary embodiment.

FIG. 11 is a sectional view of an image forming apparatus using the sensor units according to the first and second exemplary embodiments.

### DESCRIPTION OF THE EMBODIMENTS

Various exemplary embodiments, features, and aspects of the present disclosure will be illustratively described in detail below with reference to the drawings. The dimensions, materials, shapes, relative arrangements, and the like of components described in the following exemplary embodiments may be changed as appropriate depending on the configuration and various conditions of an apparatus to which the present disclosure is applied and are not meant to limit the scope of the present disclosure only to these details.

### <Description of Configuration of Sensor>

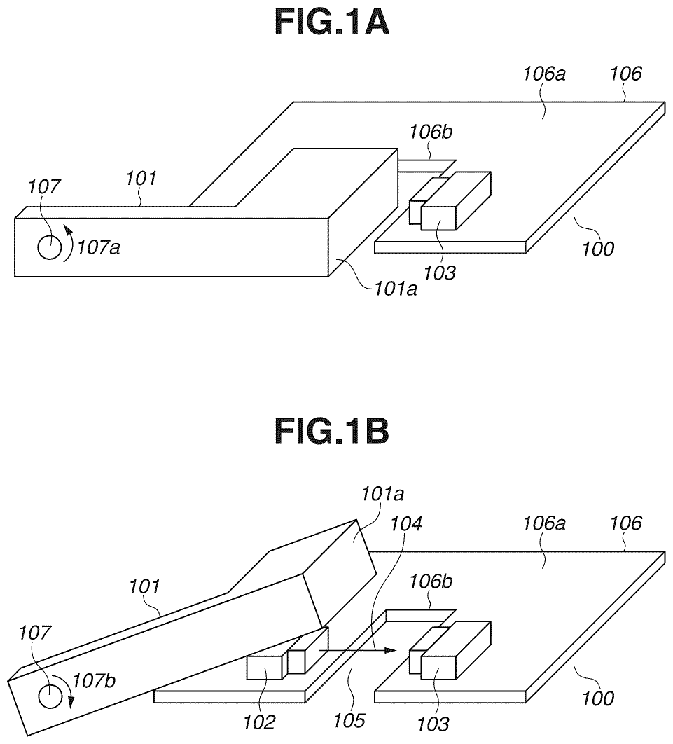

A sensor unit according to a first exemplary embodiment of the present disclosure will be described with reference to FIGS. 1A and 1B. FIGS. 1A and 1B are perspective views each illustrating the sensor unit according to the first exemplary embodiment.

The sensor unit according to the first exemplary embodiment includes an optical sensor 100 and a flag 101. The optical sensor 100 includes a light-emitting element 102 that emits light, and a light-receiving element 103 that receives the light from the light-emitting element 102. Light 104 that has been emitted from the light-emitting element 102 passes through a slit 105, which is a space obtained by cutting out a printed circuit board 106 at one side thereof, and reaches the light-receiving element 103. The optical sensor 100 detects the flag 101 based on a change in the quantity of light received by the light-receiving element 103 when the light 104 emitted from the light-emitting element 102 is blocked by a light-blocking portion 101a of the flag 101 at the slit 105. As illustrated in FIGS. 1A and 1B, the printed circuit board 106 includes an installation surface 106a on which the light-emitting element 102 and the light-receiving element 103 are placed.

The light-emitting element 102 is a surface mount type light-emitting diode (LED). A side view type light-emitting element for emitting light that travels in a straight line along the installation surface 106a of the printed circuit board 106 is used as the light-emitting element 102. The light-receiving element 103 is a surface mount type phototransistor. A side view type light-receiving element for receiving light that has traveled in a straight line along the installation surface 106a of the printed circuit board 106 is used as the light-receiving element 103. As illustrated in FIGS. 1A and 1B, an optical path of the light 104 emitted from the light-emitting element 102 to the light-receiving element 103 travels in a straight line along a direction substantially parallel to the installation surface 106a of the printed circuit board 106.

As illustrated in FIGS. 1A and 1B, the printed circuit board 106 is provided with a cutout 106b between the light-emitting element 102 and the light-receiving element 103. The cutout 106b functions as a path from which the flag 101 enters. A movement of the flag 101 passing through the cutout 106b blocks the light 104 emitted from the light-emitting element 102. As a result, the quantity of light received by the light-receiving element 103 changes, so that the flag 101 is detected.

The light-emitting element 102 and the light-receiving element 103 are placed on the same surface (installation surface 106a) of the printed circuit board 106 in such a manner that the light-emitting element 102 and the light-receiving element 103 face each other. This configuration enables the light-receiving element 103 to directly receive the light 104 that has been emitted from the light-emitting element 102 in the direction substantially parallel to the installation surface 106a of the printed circuit board 106.

### <Description of Circuit Diagram>

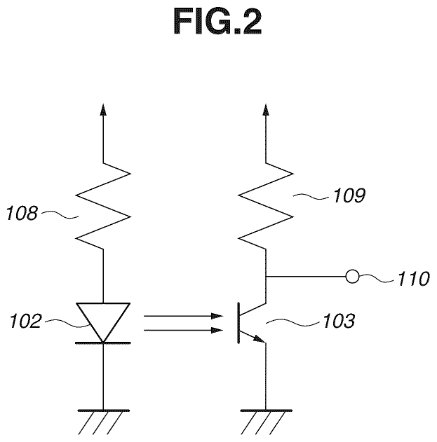

FIG. 2 is a circuit diagram of the optical sensor 100 according to the first exemplary embodiment.

The LED of the light-emitting element 102 has an anode connected to a direct current (DC) power supply via a current limit resistor 108, and a cathode connected to a ground (GND). The phototransistor of the light-receiving element 103 has a collector connected to the DC power supply via a pull-up resistor 109, and an emitter connected to the GND. A voltage output portion 110 is connected to the collector of the phototransistor, and indicates a voltage between the connector terminal of the phototransistor and the GND. The voltage output portion 110 outputs a low voltage (GND voltage) in a state where the phototransistor is turned on, or in a state where light is incident on the phototransistor. On the other hand, the voltage output portion 110 outputs a high voltage (voltage of direct current (DC) power supply) in a state where the phototransistor is turned off, or in a state where light is not incident on the phototransistor. In this configuration, the voltage of the DC power supply is 3.3 volts (V).

### <Description of Stray Light>

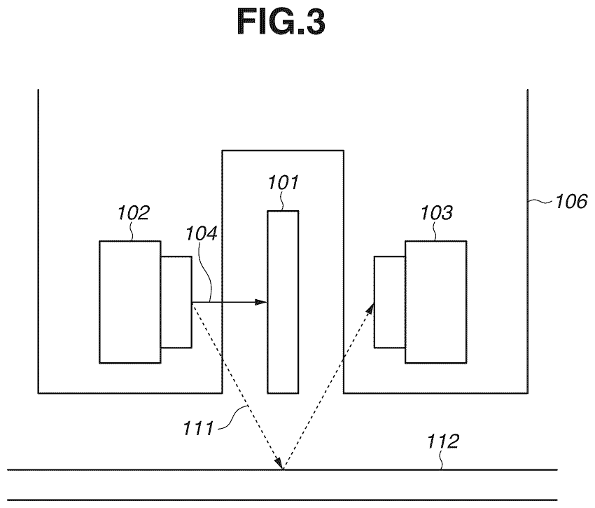

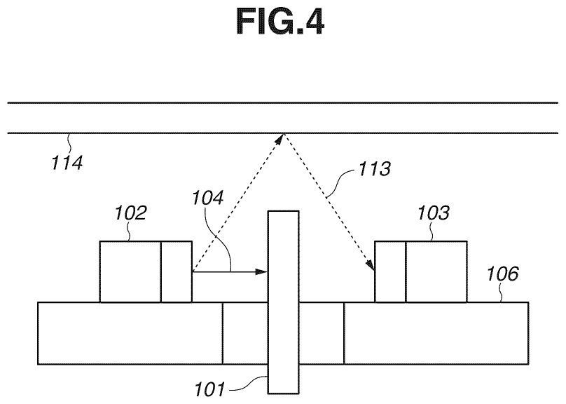

Propagation of stray light according to the first exemplary embodiment will be described with reference to FIGS. 3 and 4. The term “stray light” used herein refers to light that reaches the light-receiving element 103 through an optical path other than the optical path of light that is emitted in parallel to the installation surface 106a of the printed circuit board 106 from the light-emitting element 102 and reaches the light-receiving element 103.

FIG. 3 is a top view of the optical sensor 100. The solid arrow indicates an optical path of light 104 that has been emitted in parallel to the installation surface 106a of the printed circuit board 106 from the light-emitting element 102 and reaches the light-receiving element 103. A dashed arrow indicates an optical path of stray light 111 that is reflected on an object 112 placed on a side surface of the optical sensor 100 and reaches the light-receiving element 103. In general, light emitted from the LED has predetermined directivity and travels while spreading out. Accordingly, if the flag 101 for blocking the light emitted from the light-emitting element 102 is placed only on the front surface of the light-emitting element 102, light traveling toward the object 112 placed on the side surface of the optical sensor 100 is reflected and reaches the light-receiving element 103.

FIG. 4 is a side view of the optical sensor 100. The solid arrow indicates an optical path of light 104 that has been emitted in parallel to the installation surface 106a of the printed circuit board 106 from the light-emitting element 102 and reaches the light-receiving element 103. A broken line arrow indicates stray light 113 that is reflected on a wall 114 located on the top surface of the optical sensor 100 and reaches the light-receiving element 103. Like in the case described above with reference to FIG. 3, if the flag 101 for blocking the light emitted from the light-emitting element 102 is placed only on the front surface of the light-emitting element 102, light traveling toward the wall 114 located on the top surface of the optical sensor 100 is reflected and reaches the light-receiving element 103.

### <Description of Flag>

Examples of the shape of the flag 101 according to the first exemplary embodiment will be described with reference to FIGS. 1A, 1B, 5, 6A, and 6B.

The flag 101 illustrated in FIGS. 1A and 1B is a first example according to the first exemplary embodiment. FIG. 1A illustrates a position of the flag 101 when the light 104 emitted from the light-emitting element 102 is blocked. A rotation of the flag 101 about a rotation center 107 in a direction indicated by an arrow 107a from the position illustrated in FIG. 1A makes it possible to change the optical sensor 100 into a state where the light 104 emitted from the light-emitting element 102 reaches the light-receiving element 103.

On the other hand, FIG. 1B indicates a position of the flag 101 when the light 104 emitted from the light-emitting element 102 reaches the light-receiving element 103. A rotation of the flag 101 about the rotation center 107 in a direction indicated by an arrow 107b from the position illustrated in FIG. 1B makes it possible to change the optical sensor 100 into a state where the light emitted from the light-emitting element 102 is blocked.

In a light-blocking state, the flag 101 is configured to cover not only the element front surface, but also the element side surface and the element top surface with a wall portion that covers two directions that are perpendicular to a surface of the light-blocking portion 101a and are perpendicular to each other. This configuration makes it possible to block the path of stray light 111 that is reflected on the object 112 placed on the side surface of the optical sensor 100 and reaches the light-receiving element 103 and also block the path of stray light 113 that is reflected on the wall 114 located on the top surface, which corresponds to the installation surface side of the optical sensor 100, and reaches the light-receiving element 103.

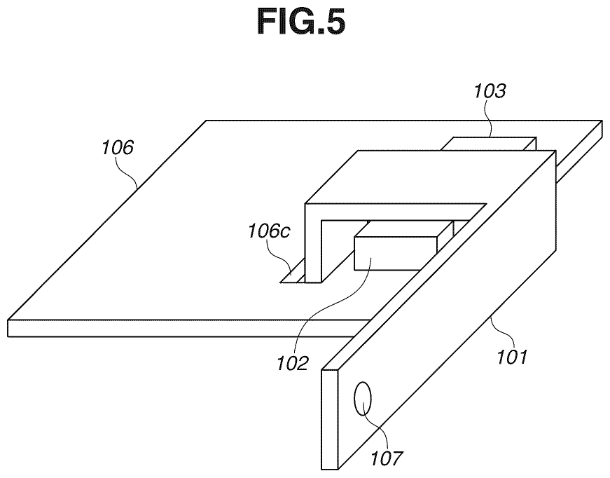

While FIGS. 1A and 1B illustrate a configuration example where only the element side surface at a substrate edge is covered, the element side surface on the opposite side of the substrate edge may be covered as illustrated in FIG. 5. This prevents the light traveling toward the opposite side of the substrate edge from the light-emitting element 102 from being reflected and reaching the light-receiving element 103.

In the configuration example illustrated in FIG. 5, the printed circuit board 106 is additionally provided with a cutout 106c, which prevents the flag 101 from contacting the printed circuit board 106 in the light-blocking state.

While FIG. 5 illustrates a configuration example where the printed circuit board 106 and the flag 101 are not in contact with each other, the flag 101 may be brought into contact with the printed circuit board 106 so as to position the flag 101 in the light-blocking state without additionally providing the cutout 106c to the printed circuit board 106.

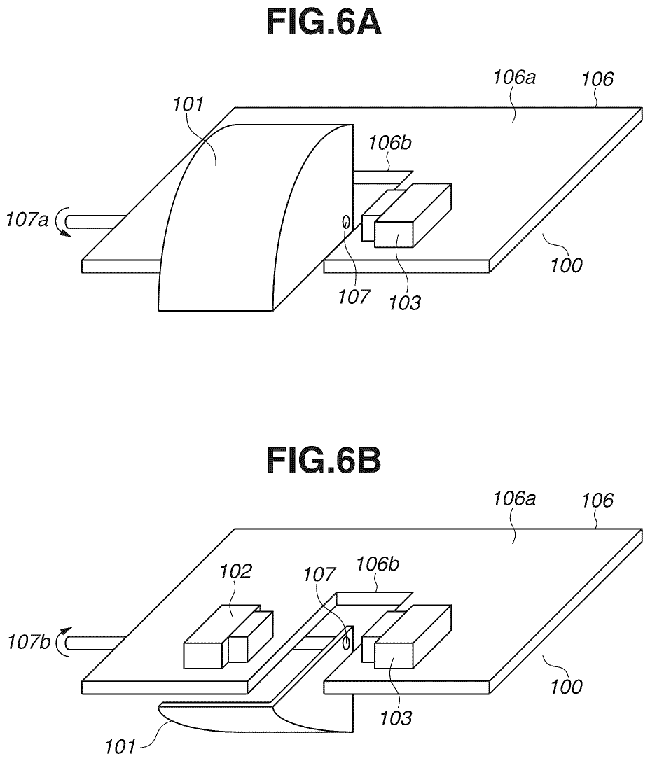

FIGS. 6A and 6B each illustrate a modified example of the first exemplary embodiment. In this example, the orientation of the rotation center 107 is 90 degrees different from that in the first embodiment described above. FIG. 6A illustrates a position of the flag 101 when the light emitted from the light-emitting element 102 is blocked. A rotation of the flag 101 in the direction indicated by the arrow 107a from the position illustrated in FIG. 6A makes it possible to change the optical sensor 100 into a state where the light emitted from the light-emitting element 102 reaches the light-receiving element 103.

On the other hand, FIG. 6B illustrates a position of the flag 101 when the light emitted from the light-emitting element 102 reaches the light-receiving element 103. A rotation of the flag 101 in the direction indicated by the arrow 107b makes it possible to change the optical sensor 100 into a state where the light emitted from the light-emitting element 102 is blocked.

Either one of the light-emitting element 102 and the light-receiving element 103 may be covered by the flag 101. In either case, it is possible to block the optical path of the stray light 111 that is reflected on the object 112 placed on the side surface of the optical sensor 100 and reaches the light-receiving element 103 and also block the optical path of the stray light 113 that is reflected on the wall 114 located on the top surface of the optical sensor 100 and reaches the light-receiving element 103.

In this case, if the light-receiving element 103 is to be covered by the flag 101, it is possible to reduce adverse effects due to ambient light. The term “ambient light” refers to light that enters from a light source different from the light-emitting element 102, such as fluorescent light or sunlight.

In the first exemplary embodiment, the flag 101 has a rotation axis, but instead may have any shape to slidably move to block light without rotation.

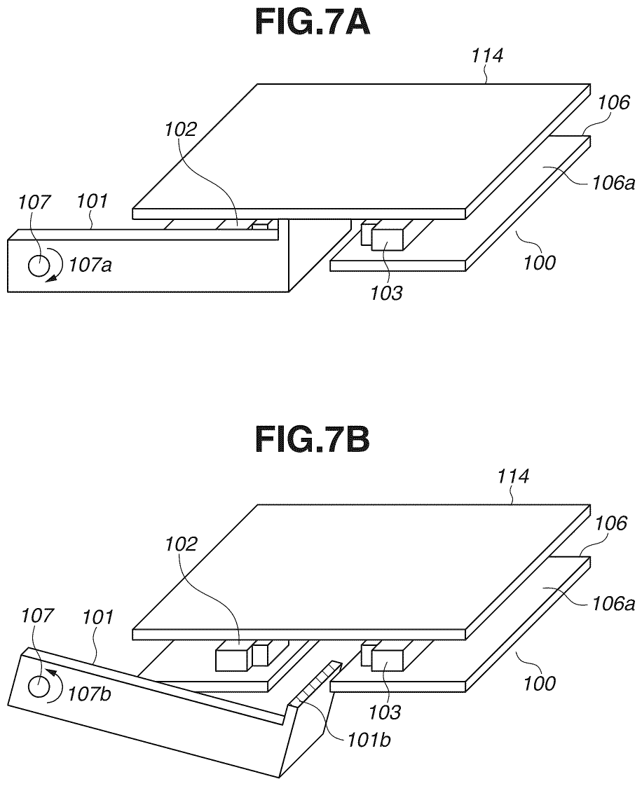

A sensor unit according to a second exemplary embodiment of the present disclosure will be described with reference to FIGS. 7A and 7B. Descriptions of components of the second exemplary embodiment that are similar to those of the first exemplary embodiment will be omitted. FIGS. 7A and 7B are perspective view each illustrating the sensor unit according to the second exemplary embodiment.

If the optical sensor 100 and the wall 114 located on the top surface of the optical sensor 100 are placed at a short distance, it is difficult to secure a sufficiently large space for the flag 101 to move above the optical sensor 100. Accordingly, in the second exemplary embodiment, the flag 101 has a shape that does not cover the element top surface and covers only the element front surface and the element side surface. FIG. 7A illustrates a position of the flag 101 in the light-blocking state. When the flag 101 is rotated about the rotation center 107 in the direction indicated by the arrow 107a from this state, the light-blocking state is released.

On the other hand, FIG. 7B illustrates a position of the flag 101 when the light emitted from the light-emitting element 102 reaches the light-receiving element 103. A rotation of the flag 101 in the direction indicated by the arrow 107b from this state makes it possible to change the optical sensor 100 into a state where the light emitted from the light-emitting element 102 is blocked.

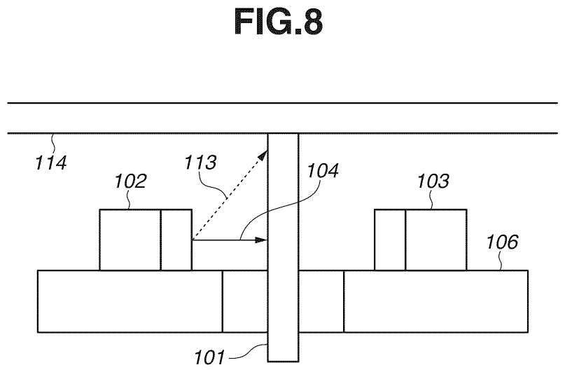

As illustrated in FIG. 7A, the flag 101 in the light-blocking state is placed in such a manner that a flag leading edge 101b indicated by a shaded area illustrated in FIG. 7B is in contact with the wall 114 located on the top surface of the optical sensor 100 with no gap therebetween. FIG. 8 is a sectional view illustrating a positional relationship among the flag 101 in the light-blocking state, the optical sensor 100, and the wall 114 located on the top surface of the optical sensor 100. As illustrated in FIG. 8, the optical path of the stray light 113 that is reflected on the wall 114 located on the top surface of the optical sensor 100 and reaches the light-receiving element 103 can be blocked without covering the element top surface side with the flag 101.

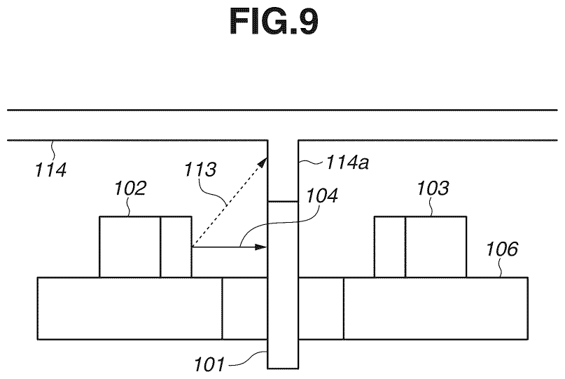

As illustrated in FIG. 9, the wall 114 located on the top surface of the optical sensor 100 may be provided with a convex shape (protruding portion) 114a and the convex shape 114a may be used as an abutting portion of the flag 101. However, in the configuration examples illustrated in FIGS. 8 and 9, if a gap is formed between the flag leading edge 101b and the wall 114 located on the top surface of the optical sensor 100 due to a backlash or the like of the flag 101, the stray light 113 can propagate to the light-receiving element 103 from the gap.

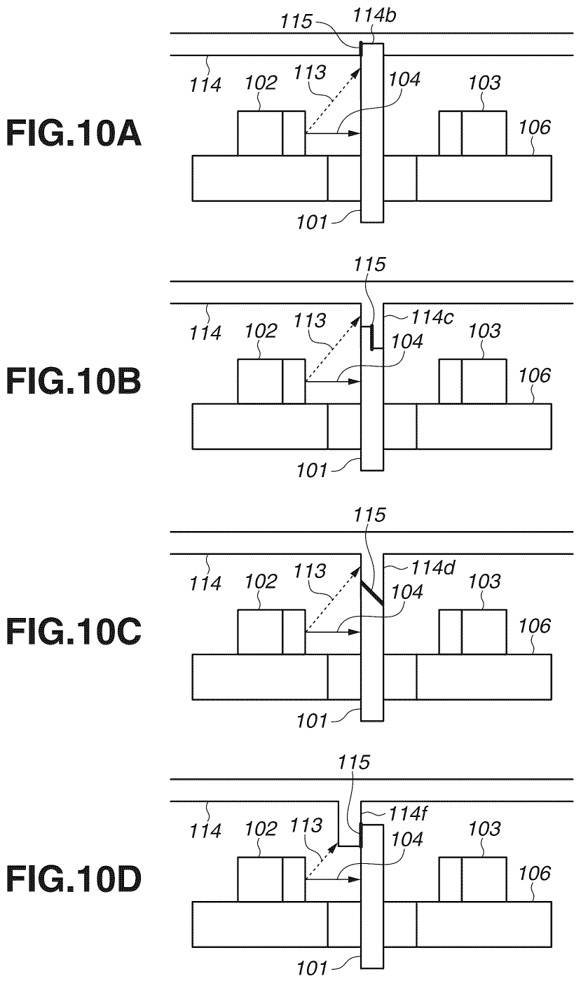

In this regard, a countermeasure against the gap between the flag leading edge 101b and the wall 114 located on the top surface of the optical sensor 100 will be described below with reference to FIGS. 10A to 10D.

FIG. 10A illustrates a configuration example where the wall 114 located on the top surface of the optical sensor 100 is provided with a concave shape 114b and the flag 101 is inserted into the concave shape 114b.

FIG. 10B illustrates a configuration example where the wall 114 located on the top surface of the optical sensor 100 is provided with a convex shape 114c having a step at the leading edge thereof. The leading edge of the flag 101 also has a step similar to the step of the convex shape 114c, and the leading edge of the convex shape 114c matches the leading edge of the flag 101 in the light-blocking state.

FIG. 10C illustrates a configuration example where the wall 114 located on the top surface of the optical sensor 100 is provided with a convex shape 114d having an obliquely cut shape at the leading edge thereof. The leading edge of the flag 101 also has an obliquely cut shape similar to that of the convex shape 114d, and the leading edge of the convex shape 114d matches the leading edge of the flag 101 in the light-blocking state.

FIG. 10D illustrates a configuration example where the flag 101 and a convex shape 114f of the wall 114 located on the top surface of the optical sensor 100 overlap each other in the light-blocking state.

In all of the configuration examples illustrated in FIGS. 10A to 10D, an overlapping portion 115 where the flag 101 and the wall 114 located on the top surface of the optical sensor 100 overlap each other is formed in the light-blocking state. This configuration prevents formation of a gap between the flag 101 and the wall 114 located on the top surface of the optical sensor 100 and prevents the stray light 113 from leaking and propagating to the light-receiving element 103 from the gap.

In the second exemplary embodiment, the flag 101 has a rotation axis, but instead may have any shape to slidably move to block light without rotation.

### <Description of Use for Door Opening/Closing Detection>

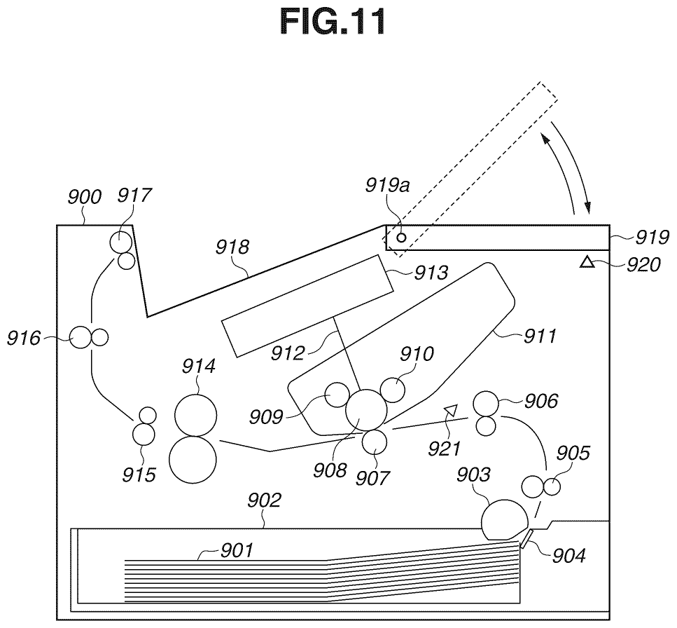

Next, an image forming apparatus using the sensor units according to the first and second exemplary embodiments will be described with reference to FIG. 11.

### (Schematic Configuration of Image Forming Apparatus)

FIG. 11 is a schematic view of an image forming apparatus 900 according to an exemplary embodiment of the present disclosure. An outline of an image forming process on a recording medium in the image forming apparatus 900 will be described with reference to FIG. 11. A photosensitive member 908 is an image carrying member that is provided in a process cartridge 911. The photosensitive member 908 is driven by a motor (not illustrated). The photosensitive member 908 develops an electrostatic latent image formed on the surface of the photosensitive member 908 with toner, and carries the developed toner image. A charging roller 909 serving as a charging member is a member for uniformly charging the surface of the photosensitive member 908. The charging roller 909 is supplied with a high voltage (also referred to as a charging bias) from a power supply circuit (not illustrated) for generating the high voltage. A laser scanner unit 913 is an exposure unit that exposes the surface of the photosensitive member 908 uniformly charged by the charging roller 909 to light to form the electrostatic latent image. The laser scanner unit 913 includes a semiconductor laser (not illustrated) for emitting a laser beam, and irradiates the surface of the photosensitive member 908 with a laser beam 912 based on image data, thereby forming the electrostatic latent image. A development roller 910 is a development member that develops a latent image by supplying toner to the electrostatic latent image formed on the surface of the photosensitive member 908, thereby forming the toner image. The development roller 910 is supplied with a high voltage (also referred to as a development bias) from the power supply circuit (not illustrated) for generating the high voltage.

Sheets 901 are stacked as recording materials in a sheet feeding cassette 902. Various types of sheets, including plain paper, thin paper, thick paper, an overhead transparency (OHT) sheet, and rough paper, can be used as the sheets 901. The sheets 901 are fed by a sheet feeding roller 903 and are separated by a frictional force of a separating pad 904 and then are fed one by one to a conveyance roller pair 905. After that, each sheet 901 passes through the conveyance roller pair 905 and a registration roller pair 906 and is conveyed to a transfer position where the photosensitive member 908 and a transfer roller 907 are in contact with each other. The transfer roller 907 is supplied with a high voltage (also referred to as a transfer bias) from the power supply circuit (not illustrated) for generating the high voltage, and transfers the toner image formed on the surface of the photosensitive member 908 to the sheet 901. A fixing roller pair 914 applies heat and pressure to the toner image to melt the toner image, thereby fixing the toner image to the sheet 901. The sheet 901 conveyed by the fixing roller pair 914 passes through discharge roller pairs 915, 916, and 917 and is discharged and stacked onto a discharge tray 918.

### (Description of Front Door)

A door 919 that also functions as an exterior cover of the image forming apparatus 900 is configured to be opened or closed with respect to a rotation fulcrum 919a. In a state where the door 919 is opened, some of process members located in the image forming apparatus 900 are exposed. The door 919 is opened or closed by, for example, an operation by an operator or a user for attachment or detachment of the process cartridge 911 that can be replaced as a unit including a photosensitive drum as the image carrying member, jam recovery processing for clearing jammed sheets 901, maintenance of the apparatus, or the like. A door sensor 920 is a sensor for detecting an open state or a closed state of the door 919, and transmits a door signal for switching a signal level from a high level to a low level by a door opening or closing operation to a central processing unit (CPU) 801 serving as a control unit.

The sensor units described in the first and second exemplary embodiments can be used as the door sensor 920. In this case, the flag 101 may be provided on the door 919 and may be configured to move with the door 919. Alternatively, the flag 101 may be provided separately from the door 919 and may be provided on a main body of the image forming apparatus 900 in such a manner that the flag 101 can be moved by a force received from the door 919 when the door 919 is closed with respect to the main body of the image forming apparatus 900.

### <Description of Use in Sheet Leading Edge Detection>

### (Description of TOP Sensor)

A TOP sensor 921 is a sensor for detecting the presence or absence of each sheet 901 at a predetermined position on a conveyance path for the sheet 901. For example, when the leading edge of the sheet 901 contacts the flag 101 and the flag 101 enters the slit 105 or the cutout 106c, the light-receiving state of the light-receiving element 103 changes and a TOP signal for switching the signal level from the high level to the low level is transmitted to the CPU 801 serving as a control unit. The TOP signal is a synchronization signal in the conveyance of the sheet 901 and is used to transfer images to a predetermined position on the sheet 901 by synchronizing the leading edge of the toner image formed on the surface of the photosensitive member 908 with the leading edge of the sheet 901.

The sensor units described in the first and second exemplary embodiments can be used as the TOP sensor 921.

The image forming apparatus 900 may be an image forming apparatus that is configured to form color images and includes a plurality of photosensitive drums and an intermediate transfer member in addition to the components illustrated in FIG. 11.

### [Supplementary Notes]

The above-described embodiments at least disclose the sensor unit below.

### (Item 1)

A sensor unit including:
a substrate on which a light-emitting element and a light-receiving element are placed, the substrate including a slit between the light-emitting element and the light-receiving element, the slit being obtained by cutting out the substrate from one side of the substrate to an inside of the substrate; and
a flag including a light-blocking portion configured to block light that travels from the light-emitting element toward the light-receiving element through the slit,
wherein the sensor unit detects the flag in a light-blocking state where the light-blocking portion of the flag blocks the light traveling from the light-emitting element toward the light-receiving element,
wherein the flag includes a wall portion configured to cover two directions perpendicular to a surface of the light-blocking portion, the two directions being perpendicular to each other, and
wherein, in the light-blocking state, the wall portion covers one of the light-emitting element and the light-receiving element in a direction perpendicular to the substrate and in a direction parallel to the substrate and in which the substrate is cut out by the slit.

### (Item 2)

A sensor unit including:
a substrate on which a light-emitting element and a light-receiving element are placed on an installation surface, the substrate including a slit between the light-emitting element and the light-receiving element, the slit being obtained by cutting out the substrate from one side of the substrate to an inside of the substrate; and
a flag including a light-blocking portion configured to block light that travels from the light-emitting element to the light-receiving element through the slit,
wherein the sensor unit detects the flag in a light-blocking state where the light-blocking portion of the flag blocks the light traveling from the light-emitting element toward the light-receiving element,
wherein a wall extending in a direction parallel to the installation surface is located on the installation surface side of the substrate,
wherein the flag includes a wall portion covering a direction perpendicular to a surface of the light-blocking portion,
wherein, in the light-blocking state, the flag moves to eliminate a gap between the flag and the wall as viewed in a direction from the light-emitting element to the light-receiving element,
wherein, in the light-blocking state, the wall covers one of the light-emitting element and the light-receiving element in a direction in which the light-emitting element and the light-receiving element are placed as viewed from the installation surface, the direction being perpendicular to the installation surface of the substrate, and
wherein, in the light-blocking state, the wall portion covers one of the light-emitting element and the light-receiving element in a direction in which the substrate is cut out by the slit, the direction being parallel to the substrate.

### (Item 3)

The sensor unit according to item 2, wherein, in the light-blocking state, the flag and the wall are in contact with each other.

### (Item 4)

The sensor unit according to items 2 and 3, wherein the wall includes a protruding portion extending in a direction perpendicular to the installation surface on the installation surface side of the substrate.

### (Item 5)

The sensor unit according to items 2 to 4, wherein, in the light-blocking state, the flag and the wall overlap each other as viewed in a direction from the light-emitting element to the light-receiving element.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Applications No. 2024-049224, filed Mar. 26, 2024, and No. 2024-223878, filed Dec. 19, 2024, which are hereby incorporated by reference herein in their entirety.

What is claimed is:

1. A sensor unit comprising:
a substrate on which a light-emitting element and a light-receiving element are placed, the substrate including a slit between the light-emitting element and the light-receiving element, the slit being obtained by cutting out the substrate from one side of the substrate to an inside of the substrate; and
a flag including a light-blocking portion configured to block light that travels from the light-emitting element toward the light-receiving element through the slit,
wherein the sensor unit detects the flag in a light-blocking state where the light-blocking portion of the flag blocks the light traveling from the light-emitting element toward the light-receiving element,
wherein the flag includes a wall portion configured to cover two directions perpendicular to a surface of the light-blocking portion, the two directions being perpendicular to each other, and
wherein, in the light-blocking state, the wall portion covers one of the light-emitting element and the light-receiving element in a direction perpendicular to the substrate and in a direction parallel to the substrate and in which the substrate is cut out by the slit.

2. A sensor unit comprising:
a substrate on which a light-emitting element and a light-receiving element are placed on an installation surface, the substrate including a slit between the light-emitting element and the light-receiving element, the slit being obtained by cutting out the substrate from one side of the substrate to an inside of the substrate; and
a flag including a light-blocking portion configured to block light that travels from the light-emitting element to the light-receiving element through the slit,
wherein the sensor unit detects the flag in a light-blocking state where the light-blocking portion of the flag blocks the light traveling from the light-emitting element toward the light-receiving element,
wherein a wall extending in a direction parallel to the installation surface is located on the installation surface side of the substrate,
wherein the flag includes a wall portion covering a direction perpendicular to a surface of the light-blocking portion,
wherein, in the light-blocking state, the flag moves to eliminate a gap between the flag and the wall as viewed in a direction from the light-emitting element to the light-receiving element,
wherein, in the light-blocking state, the wall covers one of the light-emitting element and the light-receiving element in a direction in which the light-emitting element and the light-receiving element are placed as viewed from the installation surface, the direction being perpendicular to the installation surface of the substrate, and
wherein, in the light-blocking state, the wall portion covers one of the light-emitting element and the light-receiving element in a direction in which the substrate is cut out by the slit, the direction being parallel to the substrate.

3. The sensor unit according to claim 2, wherein, in the light-blocking state, the flag and the wall are in contact with each other.

4. The sensor unit according to claim 2, wherein the wall includes a protruding portion extending in a direction perpendicular to the installation surface on the installation surface side of the substrate.

5. The sensor unit according to claim 2, wherein, in the light-blocking state, the flag and the wall overlap each other as viewed in a direction from the light-emitting element to the light-receiving element.
